(19) United States
(12) Patent Application Publication
(10) Pub. No.: US 2005/0087877 A1
(43) Pub. Date: Apr. 28, 2005

(54) Differential signal traces coupled with high permittivity material

(76) Inventors: Dong-Ho Han, Phoenix, AZ (US); Joong-Ho Kim, Phoenix, AZ (US); Jiangqi He, Gilbert, AZ (US); Hyunjun Kim, Chandler, AZ (US)

Correspondence Address: BUCKLEY, MASCHOFF, TALWALKAR LLC, 5 ELM STREET, NEW CANAAN, CT, 06840, US

(21) Appl. No.: 10/690,928

(22) Filed: Oct. 22, 2003

(51) Int. Cl. H01L 23/48; H01L 23/52

(52) U.S. Cl. 257/758

(57) ABSTRACT

In some embodiments, an apparatus includes a substrate and a pair of signal traces formed on the substrate. The signal traces may be spaced apart from each other. The apparatus may also include a filler material on the substrate and between the signal traces. The filler material may have a dielectric constant that is higher than a dielectric constant of a material of which the substrate is formed.

### BACKGROUND

A pair of signal traces on a printed circuit board (PCB) may be used for differential signaling. For reasons of cost and/or durability, it may be desirable to utilize an inhomogeneous substrate material for the PCB. For example, a resin in which fibers are embedded may be used as the substrate material. The inhomogeneous nature of the substrate material may interfere with proper differential signaling in the signal traces. If one of the two traces passes over a fiber and the other does not, common mode noise may result, which may cause a departure from the 180° output phase difference to be maintained in the respective signals in the two signal traces. The resulting degradation of the differential signal may prevent transmission from being successfully carried out.

Also, PCB design practices generally call for a minimum limit on the spacing between two adjacent signal traces. As a result, there may be a limit to the degree to which low differential impedance and high coupling can be achieved between two signal traces used for differential signaling. This may limit the extent to which the common mode rejection ratio can be reduced.

### BRIEF DESCRIPTION OF THE DRAWINGS

FIG. 1 is a schematic cross-sectional view of a circuit board provided according to some embodiments.

FIG. 2 is a simplified block diagram illustration of the circuit board of FIG. 1.

FIG. 3 is flow chart that illustrates a process that may be used to form a pair of signal traces and a high permittivity filler material layer between the signal traces according to some embodiments.

FIG. 4 is a flow chart that illustrates an alternative process that may be used to form a pair of signal traces and a high permittivity filler material layer between the signal traces according to some embodiments.

### DETAILED DESCRIPTION

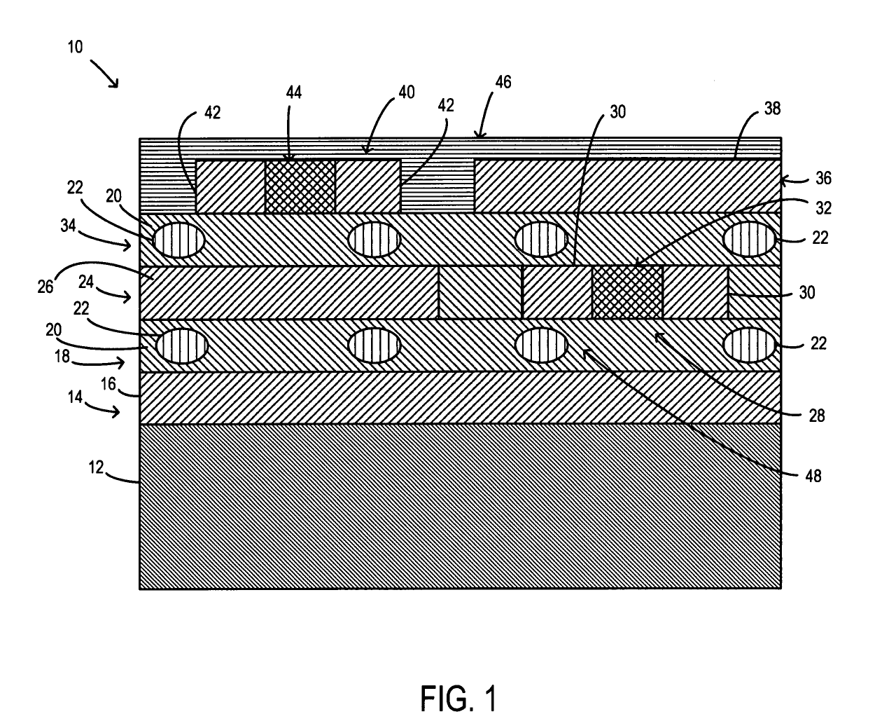

FIG. 1 is a schematic cross-sectional view of a circuit board 10 provided according to some embodiments. The circuit board 10 includes a core or base layer 12 which may be formed of a thick dielectric material. The circuit board 10 also includes a first metallization level 14 which may be implemented as a continuous ground plane 16 on the core layer 12. In some embodiments, the ground plane 16 may be formed of copper. An intermediate dielectric layer 18 may be formed on the first metallization layer 14. The intermediate dielectric layer 18 may be formed of an inhomogeneous material such as an epoxy resin 20 in which fibers 22 are embedded. The fibers 22 add to the mechanical strength of the circuit board 10.

A second metallization layer 24 is formed on the intermediate dielectric layer 18. A portion of the second metallization layer 24 is formed as a ground plane 26. Also formed as part of the second metallization layer 24 is a stripline structure 28 that includes a pair of signal traces 30. The signal traces 30 and the ground plane 26 may be formed of copper. The signal traces 30 are formed on the intermediate dielectric layer 18 which serves as a substrate for the signal traces 30. A high permittivity filler material layer 32, to be discussed further below, is also formed on the intermediate dielectric layer 18 between the signal traces 30. The filler material layer 32 may completely fill the space between the signal traces 30 and may have the same height as the signal traces 30.

Another intermediate dielectric layer 34 may be formed on the second metallization layer 24. Like the dielectric layer 18, the dielectric layer 34 may be formed of an inhomogeneous material such as an epoxy resin 20 in which fibers 22 are embedded. The dielectric layer 34 may be of the same composition as the dielectric layer 18.

A third metallization layer 36 is formed on the dielectric layer 34. A portion of the third metallization layer 36 is formed as a second ground plane 38 for the stripline structure 28. Also formed as part of the third metallization layer 36 is a microstrip structure 40 that includes a pair of signal traces 42. The signal traces 42 and the ground plane 38 may be formed of copper. The signal traces 42 are formed on the dielectric layer 34 which serves as a substrate for the signal traces 42. A high permittivity filler material layer 44, to be discussed further below, is also formed on the dielectric layer 34 between the signal traces 42. The filler material layer 44 may have the same composition as the filler material layer 32. The filler material layer 44 may completely fill the space between the signal traces 42 and may have the same height as the signal traces 42.

A solder mask layer 46 is formed on the third metallization layer 36 and is also formed on the dielectric layer 34 and locations where the third metallization layer 36 and the filler material layer 44 do not cover the dielectric layer 34.

Except for the filler material layers 32 and 44, the circuit board 10 may be constructed in accordance with conventional practices. The filler material layers 32 and 44 may be formed of a high permittivity material that has a dielectric constant that is higher than the dielectric constant of the resin 20 of the dielectric layers 18 and 34. Also, the dielectric constant of the filler material layers 32 and 44 may be higher than the dielectric constant of the solder mask layer 46. The high permittivity of the filler material layers 32 and 44 may allow for tighter coupling of signal traces 30 to each other or of the signal traces 42 to each other, as the case may be. The differential impedance in the microstrip structure 40 or the stripline structure 28 may be reduced, so that greater common mode rejection is provided. The reduction in impedance may be accomplished without reducing the spacing between the signal traces 30 or between the signal traces 42, as the case may be. In addition, for a given level of differential impedance, the width of the signal traces may be reduced with the inclusion of the high permittivity material layers 32 or 44, so that greater trace density may be realized.

Furthermore, since most of the signal energy is carried by the filler material layers 32 and 44, the presence of a fiber in the dielectric layer 18 or 34 adjacent one of the signal traces (as indicated, for example at 48) is less likely to affect the phase velocity of the signal in the signal trace. Consequently, it is less likely that the inhomogeneousness of the dielectric layer may adversely affect the differential signaling in the pair of signal traces. Also, it may not be necessary to utilize a higher cost, and possible less structurally strong, homogeneous material for the dielectric layers.

One example of a material that may be suitable for use as the filler material layers 32 and 44 is polyvinylidene difluoride. Other high-K materials may be used, including materials that incorporate ceramic particles. In some embodiments, any suitable material having a dielectric constant in excess of 4 may be used.

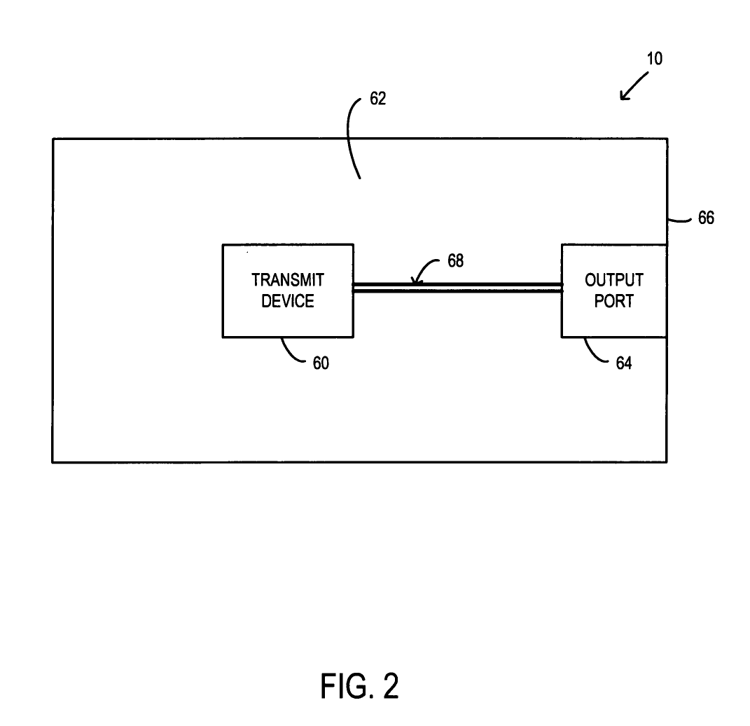

FIG. 2 is a partial schematic block diagram that illustrates aspects of the circuit board 10. A transmit device 60 is carried on the circuit board 10. The transmit device may be any type of device capable of transmitting differential signals. The circuit board 10 also includes a substrate 62 (e.g., one of the dielectric layers described with reference to FIG. 1). Further, an output port 64 is present at an edge 66 of the circuit board 10 to allow for edge coupling of the differential signals transmitted by the transmit device 60. Also, the circuit board includes a pair of signal traces 68 formed on the substrate 62 to carry the differential signal from the transmit device 60 to the output port 64. The signal traces 68 may be constituted, for example, by the stripline structure 28 described with reference to FIG. 1 or by the microstrip structure 40 described with reference to FIG. 1. In any case, the circuit board 10 may include a filler material layer (not separately shown in FIG. 2) on the substrate and between the signal traces. This filler material layer may be like the layers 32 and 44 described above in connection with FIG. 1.

Although not shown in FIG. 2 to simplify the drawing, the circuit board 10 may include or carry other devices and features in addition to those illustrated in FIG. 2.

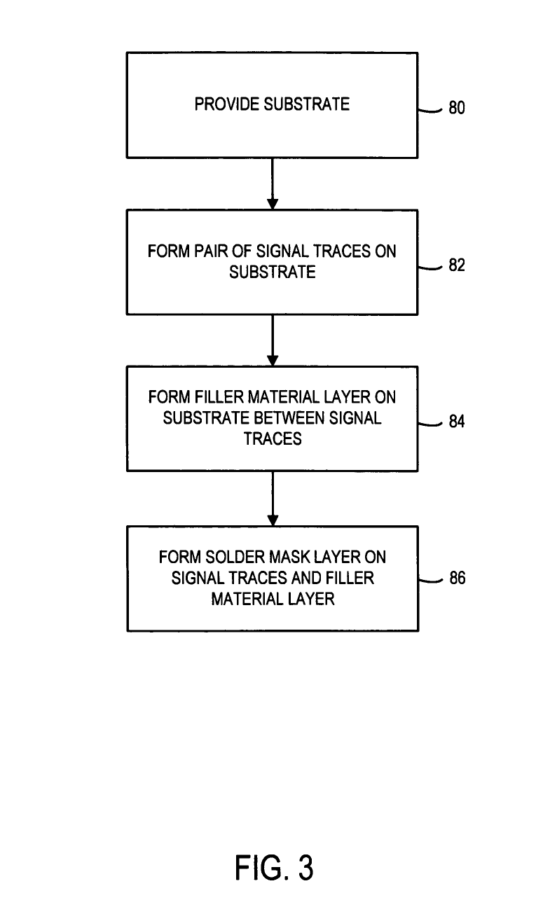

FIG. 3 is a flow chart that illustrates a process that may be performed according to some embodiments in connection with manufacturing the circuit board 10.

As indicated at 80 in FIG. 3, a substrate such as one of the dielectric layers 18 or 34 (FIG. 1) may be provided. Then, at 82 in FIG. 3, a pair of signal traces (e.g., traces 30 or traces 42) are formed on the substrate. The traces may, for example, be formed spaced apart from each other so as to form a microstrip structure or a stripline structure suitable for carrying differential signals. A conventional imprinting operation may be employed to form the signal traces.

Next, at 84, a filler material layer is formed on the substrate between the signal traces. The filler material may be a high permittivity material, as described above. An imprinting operation in accordance with conventional principles may be employed to form the filler material layer. As indicated at 86, a solder mask layer may be formed on the signal traces and on the filler material layer.

The filler material may have a dielectric constant that is higher than the dielectric constant of a material (e.g., a resin) of which the substrate is formed. The dielectric constant of the filler material may also be higher than the dielectric constant of the solder mask. The filler material layer formed at 84 may have a height that is substantially equal to the height of the signal traces. The filler material layer may be formed so as to substantially fill the space between the signal traces.

Other operations to manufacture the circuit board, which are not indicated in FIG. 3, may be performed before and/or after the operations illustrated in FIG. 3.

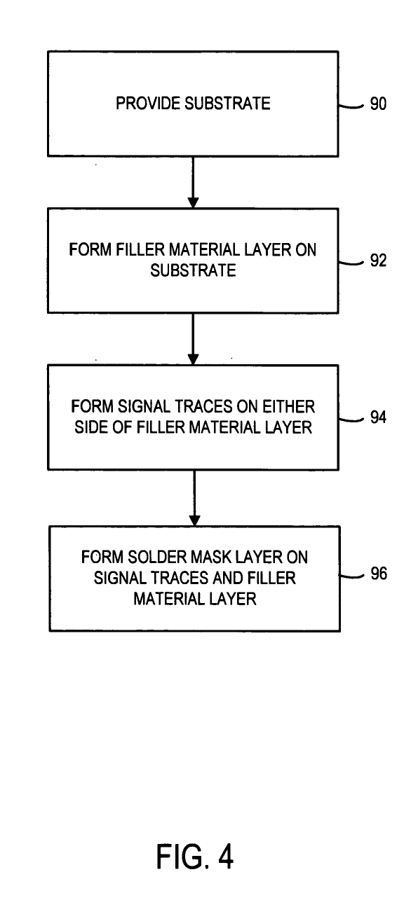

FIG. 4 is a flow chart that illustrates an alternative process that may be performed according to some embodiments in connection with manufacturing the circuit board 10.

As indicated at 90 in FIG. 4, a substrate such as one of the dielectric layers 18 or 34 (FIG. 1) may be provided. Then, at 92 in FIG. 4, a filler material layer is formed on the substrate. The filler material may be a high permittivity material, as described above. An imprinting operation in accordance with conventional principles may be employed to form the filler material layer.

Next, at 94, a pair of signal traces (e.g., traces 30 or traces 42) may be formed on the substrate. The traces may be formed so that each of the traces is on a respective side of the filler material layer. That is, the traces may be formed on either side of the filler material layer, such that the traces are spaced from each other with the filler material layer in between the traces. The space between the traces may be substantially filled by the filler material layer, and the height of the filler material layer may be substantially the same as the height of the traces. The traces may be formed in accordance with a conventional imprinting operation.

As indicated at 96, a solder mask layer may be formed on the signal traces and on the filler material layer.

The filler material may have a dielectric constant that is higher than the dielectric constant of a material (e.g., a resin) of which the substrate is formed. The dielectric constant of the filler material may also be higher than the dielectric constant of the solder mask.

Other operations to manufacture the circuit board, which are not indicated in FIG. 4, may be performed before and/or after the operations illustrated in FIG. 4.

The example embodiment shown in FIG. 1 is a circuit board that has three metallization layers. In other embodiments, a circuit board may have more or fewer than three metallization layers.

Instead of having both microstrip and stripline structures as shown in FIG. 1, in some embodiments a circuit board may have only microstrip structures or only stripline structures.

In embodiments described above, a high permittivity filler material is used between signal traces formed on a composite substrate. In other embodiments, the high permittivity filler material may be used between signal traces formed on a homogeneous substrate.

The several embodiments described herein are solely for the purpose of illustration. The various features described herein need not all be used together, and any one or more of those features may be incorporated in a single embodiment. Therefore, persons skilled in the art will recognize from this description that other embodiments may be practiced with various modifications and alterations.

1. An apparatus comprising:
a substrate;
a pair of signal traces formed on the substrate and spaced from each other; and
a filler material on the substrate and between the signal traces, the filler material having a dielectric constant that is higher than a dielectric constant of a material of which the substrate is formed.

2. The apparatus of claim 1, further comprising:
a solder mask layer on the signal traces and on the filler material, the dielectric constant of the filler material being higher than a dielectric constant of the solder mask layer.

3. The apparatus of claim 1, wherein the substrate includes a resin in which fibers are embedded, the dielectric constant of the filler material being higher than a dielectric constant of the resin.

4. The apparatus of claim 1, wherein the signal traces are formed of copper.

5. The apparatus of claim 1, wherein the filler material substantially fills a space between the signal traces.

6. The apparatus of claim 1, wherein the filler material has a height that is substantially equal to a height of the signal traces.

7. The apparatus of claim 1, wherein the filler material has a dielectric constant in excess of 4.

8. A method comprising:
providing a substrate;
forming a pair of signal traces spaced apart from each other on the substrate; and
forming a filler material layer on the substrate between the signal traces;
wherein the filler material has a dielectric constant that is higher than a dielectric constant of a material of which the substrate is formed.

9. The method of claim 8, further comprising:
forming a solder mask layer on the signal traces and on the filler material layer;
wherein the dielectric constant of the filler material is higher than a dielectric constant of the solder mask.

10. The method of claim 8, wherein the substrate includes a resin in which fibers are embedded, the dielectric constant of the filler material being higher than a dielectric constant of the resin.

11. The method of claim 8, wherein the signal traces are formed of copper.

12. The method of claim 8, wherein the filler material layer substantially fills a space between the signal traces.

13. The method of claim 8, wherein the filler material layer has a height that is substantially equal to a height of the signal traces.

14. The method of claim 8, wherein the filler material layer is formed of a material having a dielectric constant in excess of 4.

15. A method comprising:
providing a substrate;
forming a filler material layer on the substrate; and
forming a pair of signal traces on the substrate, each of the signal traces being on a respective side of the filler material layer;
wherein the filler material has a dielectric constant that is higher than a dielectric constant of a material of which the substrate is formed.

16. The method of claim 15, further comprising:
forming a solder mask layer on the signal traces and on the filler material layer;
wherein the dielectric constant of the filler material is higher than a dielectric constant of the solder mask.

17. The method of claim 15, wherein the substrate includes a resin in which fibers are embedded, the dielectric constant of the filler material being higher than a dielectric constant of the resin.

18. The method of claim 15, wherein the signal traces are formed of copper.

19. The method of claim 15, wherein the filler material layer substantially fills a space between the signal traces.

20. The method of claim 15, wherein the filler material layer has a height that is substantially equal to a height of the signal traces.

21. The method of claim 15, wherein the filler material layer is formed of a material having a dielectric constant in excess of 4.

22. A system comprising:
a circuit board;
a transmit device on the circuit board to transmit a differential signal; and
an output port on the circuit board to receive the differential signal;
wherein the circuit board includes:
a substrate;
a pair of signal traces formed on the substrate to carry the differential signal from the transmit device to the output port; and
a filler material on the substrate and between the signal traces, the filler material having a dielectric constant that is higher than a dielectric constant of a material of which the substrate is formed.

23. The system of claim 22, wherein the circuit board further includes a solder mask layer on the signal traces and on the filler material, the dielectric constant of the filler material being higher than a dielectric constant of the solder mask layer.

24. The system of claim 22, wherein the substrate includes a resin in which fibers are embedded, the dielectric constant of the filler material being higher than a dielectric constant of the resin.

25. The system of claim 22, wherein the signal traces are formed of copper.

26. The system of claim 22, wherein the filler material substantially fills a space between the signal traces.

27. The system of claim 22, wherein the filler material has a height that is substantially equal to a height of the signal traces.

28. The system of claim 22, wherein the filler material has a dielectric constant in excess of 4.
